(19) United States
(12) Patent Application Publication
(10) Pub. No.: US 2026/0107857 A1
(43) Pub. Date: Apr. 16, 2026

(54) METHODS OF BONDING A SEMICONDUCTOR ELEMENT TO A SUBSTRATE

(71) Applicant: Kulicke and Soffa Industries, Inc., Fort Washington, PA (US)

(72) Inventor: Thomas J. Colosimo, JR., West Chester, PA (US)

(73) Assignee: Kulicke and Soffa Industries, Inc., Fort Washington, PA (US)

(21) Appl. No.: 19/342,529

(22) Filed: Sep. 27, 2025

Related U.S. Application Data
(60) Provisional application No. 63/706,698, filed on Oct. 13, 2024.

(51) Int. Cl. H01L 23/00

(52) U.S. Cl. CPC H10W 99/00; H10W 72/90; H10W 72/952; H10W 80/016; H10W 80/041; H10W 80/312; H10W 80/327

(57) ABSTRACT

A method of bonding a semiconductor element to a substrate is provided. The method includes the steps of: (a) carrying the semiconductor element with a bonding tool, the semiconductor element including a first plurality of conductive structures; (b) supporting the substrate with a support structure, the substrate including a second plurality of conductive structures; (c) heating at least one of the first plurality of conductive structures and the second plurality of conductive structures such that at least one of (i) the first plurality of conductive structures and (ii) the second plurality of conductive structures expands; (d) bonding the first plurality of conductive structures to corresponding ones of the second plurality of conductive structures; and (e) bonding a dielectric surface of the semiconductor element to a dielectric surface of the substrate after step (d).

### CROSS-REFERENCE TO RELATED APPLICATION

This application claims the benefit of U.S. Provisional Application No. 63/706,698, filed on Oct. 13, 2024, the content of which is herein incorporated by reference.

### FIELD

The invention relates to bonding systems and processes, and more particularly, to improved systems and methods for bonding a semiconductor element to a substrate.

### BACKGROUND

Traditional semiconductor packaging typically involves die attach processes and wire bonding processes. Advanced semiconductor packaging technologies (e.g., flip chip bonding, thermocompression bonding, etc.) technologies continue to gain traction in the industry. For example, in thermocompression bonding (i.e., TCB), heat and/or pressure (and sometimes ultrasonic energy) are used to form a plurality of interconnections between (i) conductive structures on a semiconductor element and (ii) conductive structures on a substrate. In certain flip chip bonding or thermocompression bonding applications, the conductive structures of the semiconductor element and/or the substrate may include surface oxides that can impair bond quality. This is especially an issue if the conductive structures are formed of (or include) copper or similar materials (e.g., copper pillars).

In such applications, it is desirable to provide an environment suitable for bonding. For example, such an environment may be provided by using a deoxidizing agent (e.g., a reducing gas, a plasma gas, a gas including attached electrons, etc.). For example, a reducing gas may be provided at the bonding area to reduce potential oxidation and/or contamination of the conductive structures of the semiconductor element or the substrate to which it will be bonded. Example patents and patent applications related to such a reducing gas environment include: U.S. Pat. No. 10,861,820 (entitled “METHODS OF BONDING SEMICONDUCTOR ELEMENTS TO A SUBSTRATE, INCLUDING USE OF A REDUCING GAS, AND RELATED BONDING MACHINES”); U.S. Pat. No. 11,205,633 (entitled “METHODS OF BONDING OF SEMICONDUCTOR ELEMENTS TO SUBSTRATES, AND RELATED BONDING SYSTEMS”); U.S. Pat. No. 11,515,286 (entitled “METHODS OF BONDING OF SEMICONDUCTOR ELEMENTS TO SUBSTRATES, AND RELATED BONDING SYSTEMS”); U.S. Patent Application Publication No. 2023/0133526 (entitled “BONDING SYSTEMS FOR BONDING OF SEMICONDUCTOR ELEMENTS TO SUBSTRATES, AND RELATED METHODS”); U.S. Patent Application Publication No. 2023/0260953 (entitled “METHODS OF MONITORING GAS BYPRODUCTS OF A BONDING SYSTEM, AND RELATED MONITORING SYSTEMS AND BONDING SYSTEMS”); U.S. Pat. No. 12,062,636 (entitled “BONDING SYSTEMS, AND METHODS OF PROVIDING A REDUCING GAS ON A BONDING SYSTEM”); U.S. Patent Application Publication No. 2024/0063169 (entitled “BONDING SYSTEMS FOR BONDING A SEMICONDUCTOR ELEMENT TO A SUBSTRATE, AND RELATED METHODS”); and U.S. Patent Application Publication No. 2024/0332244 (entitled “METHODS OF PROCESSING A SUBSTRATE ON A BONDING SYSTEM, AND RELATED BONDING SYSTEMS”). These references are incorporated by reference herein in their entirety.

Thus, it would be desirable to provide improved methods of bonding semiconductor elements to a substrate.

### SUMMARY

According to an exemplary embodiment of the invention, a method of bonding a semiconductor element to a substrate is provided. The method includes the steps of: (a) carrying the semiconductor element with a bonding tool, the semiconductor element including a first plurality of conductive structures (e.g., electrically conductive structures); (b) supporting the substrate with a support structure, the substrate including a second plurality of conductive structures (e.g., electrically conductive structures); (c) heating at least one of the first plurality of conductive structures and the second plurality of conductive structures such that at least one of the first plurality of conductive structures and the second plurality of conductive structures expands; (d) bonding the first plurality of conductive structures to corresponding ones of the second plurality of conductive structures; and (e) bonding a dielectric surface of the semiconductor element to a dielectric surface of the substrate after step (d).

According to other embodiments of the invention, the method of the immediately preceding paragraph may have any one or more of the following features: wherein during step (c) the first plurality of conductive structures are heated by a first heater engaged with the bonding tool, and the second plurality of conductive structures are heated by a second heater engaged with the support structure; wherein during step (c) at least one of (i) the first plurality of conductive structures and (ii) the second plurality of conductive structures are heated using laser energy; wherein during step (c) each of the first plurality of conductive structures and the second plurality of conductive structures expands; wherein during step (c) each of the first plurality of conductive structures and the second plurality of conductive structures expand in a range of 5 to 100 nanometers; wherein during step (c) each of the first plurality of conductive structures and the second plurality of conductive structures expand in a range of 20 to 80 nanometers; wherein at room temperature the first plurality of conductive structures are substantially planar with a dielectric surface of the semiconductor element; wherein at room temperature the first plurality of conductive structures are recessed with respect to the dielectric surface of the semiconductor element; wherein at room temperature the first plurality of conductive structures protrude with respect to the dielectric surface of the semiconductor element; wherein at room temperature the second plurality of conductive structures are substantially planar with the dielectric surface of the substrate; wherein at room temperature the second plurality of conductive structures are recessed with respect to the dielectric surface of the substrate; wherein at room temperature the second plurality of conductive structures protrude with respect to the dielectric surface of the substrate; wherein the first plurality of conductive structures and the second plurality of conductive structures are formed of copper; wherein the first plurality of conductive structures and the second plurality of conductive structures are formed of a copper alloy; wherein the dielectric surface of the semiconductor element is bonded to the dielectric surface of the substrate during step (e) because of contraction of expansion that occurred during step (c); wherein the dielectric surface of the semiconductor element is configured to fuse to the dielectric surface of the substrate during step (e) because of contact therebetween; wherein contact between (i) the dielectric surface of the semiconductor element and (ii) the dielectric surface of the substrate is caused by contraction of expansion that occurred during step (c); further comprising a step of providing a deoxidizing agent in contact with the first plurality of conductive structures prior to and/or during step (c); wherein the deoxidizing agent includes at least one of a reducing gas and a plasma gas; and wherein the deoxidizing agent includes a reducing gas, the reducing gas including formic acid.

### BRIEF DESCRIPTION OF THE DRAWINGS

The invention is best understood from the following detailed description when read in connection with the accompanying drawings. Throughout the various drawings, like reference numerals refer to the like elements, except where explained herein. It is emphasized that, according to common practice, the various features of the drawings are not to scale. On the contrary, the dimensions of the various features are arbitrarily expanded or reduced for clarity. Included in the drawings are the following figures:

FIGS. 1A-1E are cross-sectional side views of a bonding system for bonding a semiconductor element to a substrate in accordance with an exemplary embodiment of the invention; and

FIG. 2 is a flow diagram illustrating a method of bonding a semiconductor element to a substrate in accordance with an exemplary embodiment of the invention.

### DETAILED DESCRIPTION

In certain TCB processes, a semiconductor element (e.g., a source die) may be brought to an appropriate distance (e.g., 1-2 mm) away from a target substrate. A deoxidizing agent (e.g., a reducing gas, a formic acid vapor, plasma, plasma gas, etc.) may be provided (e.g., injected) at or near the semiconductor element and/or the target substrate. At the same time, the semiconductor element (and/or the substrate) may be heated such that the conductive structures (e.g., conductive structures formed of copper or a copper alloy) of the semiconductor element (and/or the substrate) are heated such that they expand. The conductive structures of the semiconductor element and the substrate are then bonded together with a small gap between the dielectric surface of the semiconductor element and the dielectric surface of the substrate (e.g., where the gap is at least partially caused by the expansion of the conductive structures). When the temperature of conductive structures of the semiconductor element (and/or of the substrate) is reduced, the gap decreases, and the dielectric surface of the semiconductor element is bonded to the dielectric surface of the substrate. For example, the composition of the dielectric surface of the semiconductor element is configured to fuse to the composition of the dielectric surface of the substrate when they contact one another.

As used herein, the term “semiconductor element” is intended to refer to any structure including (or configured to include at a later step) a semiconductor chip or die. Exemplary semiconductor elements include a bare semiconductor die, a semiconductor die on a substrate (e.g., a leadframe, a PCB, a carrier, a semiconductor chip, a semiconductor wafer, a BGA substrate, a semiconductor element, etc.), a packaged semiconductor device, a flip chip semiconductor device, a die embedded in a substrate, a stack of semiconductor die, amongst others. Further, the semiconductor element may include an element configured to be bonded or otherwise included in a semiconductor package (e.g., a spacer to be bonded in a stacked die configuration, a substrate, etc.).

As used herein, the term “substrate” is intended to refer to any structure to which a semiconductor element may be bonded. Exemplary substrates include, for example, a leadframe, a PCB, a carrier, a module, a semiconductor chip, a semiconductor wafer, a BGA substrate, another semiconductor element, etc.

In accordance with certain exemplary embodiments of the invention, a bonding system is provided using a deoxidizing agent (e.g., a reducing gas such as formic acid vapor, a plasma gas, etc.). The bonding system may be, for example, a flip chip bonding system, a thermocompression bonding system, a thermosonic bonding system, etc.

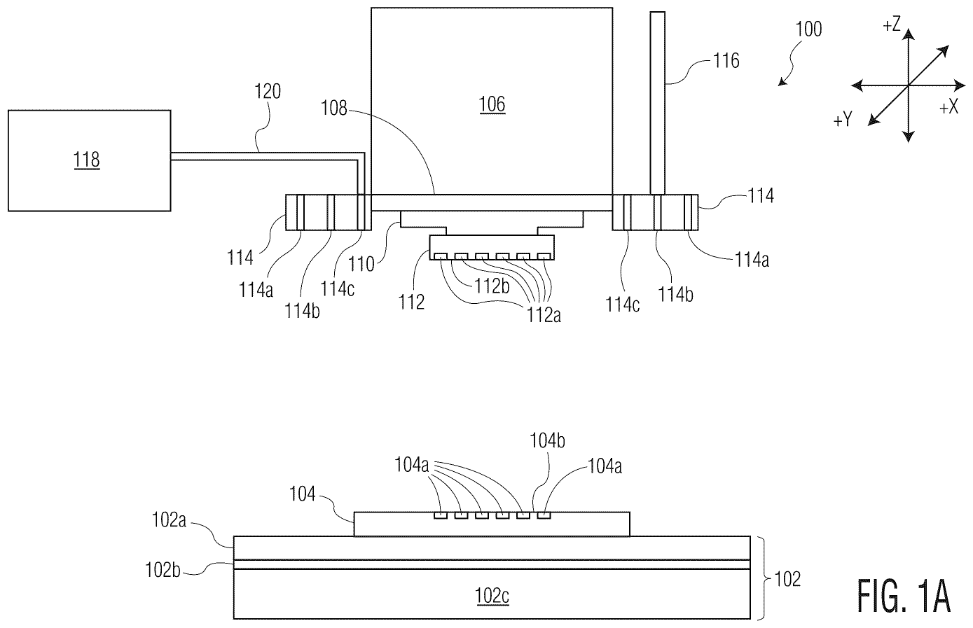

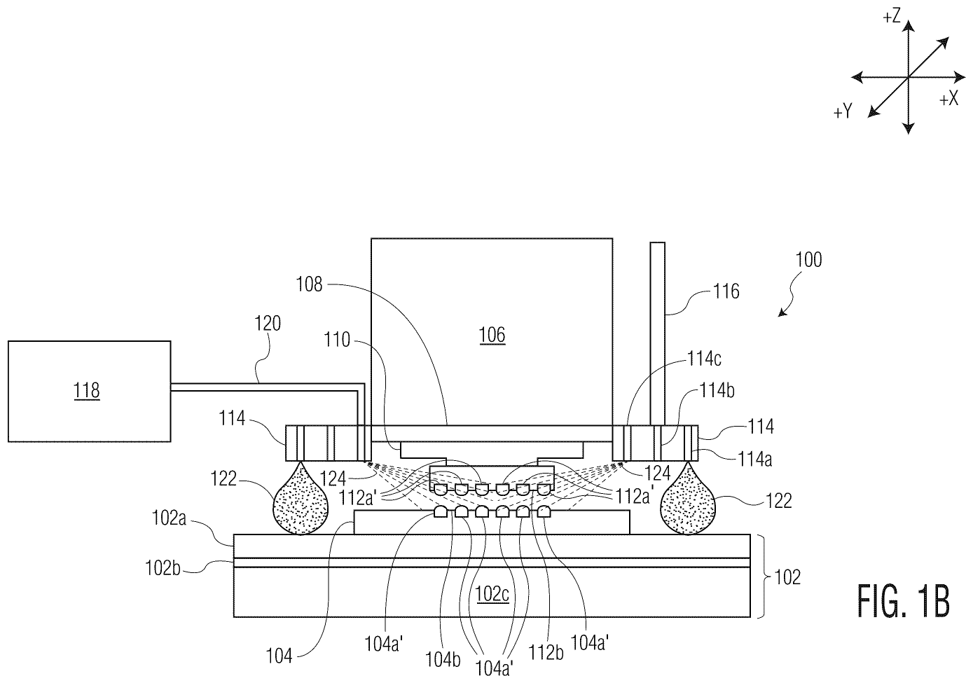

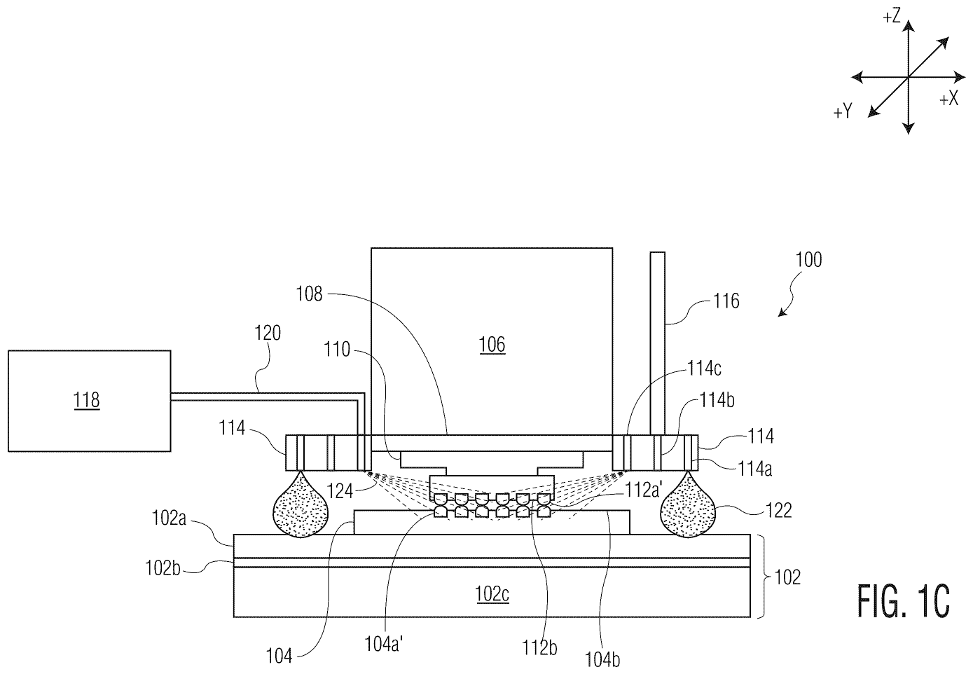

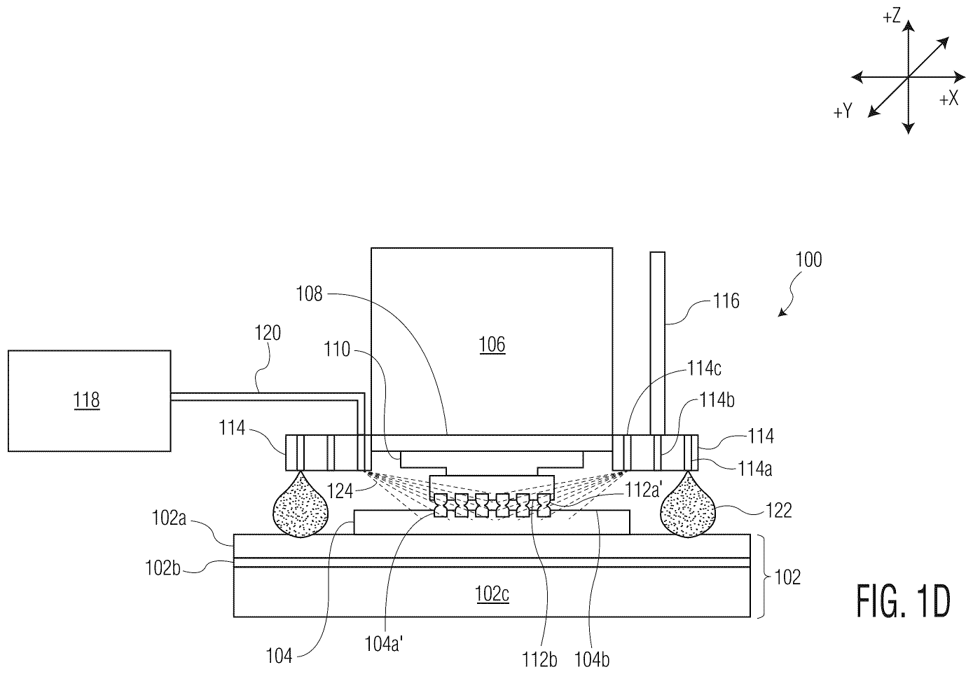

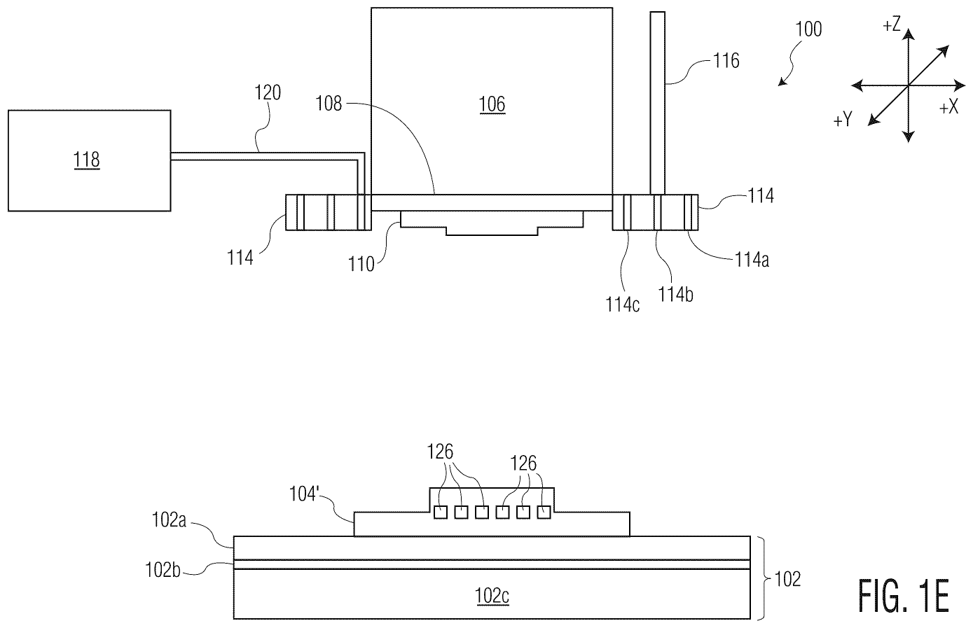

Referring now to FIGS. 1A-1E, a bonding machine 100 (e.g., a flip chip bonding machine, a thermocompression bonding machine, etc.) is illustrated in connection with certain exemplary embodiments of the invention. Bonding machine 100 includes a bond head assembly 106, which may be configured to move along (and about) a plurality of axes of bonding machine 100 (e.g., the x-axis, y-axis, z-axis, a rotative/theta axis, etc.). Bond head assembly 106 includes a heater 108 and a bonding tool 110. In certain embodiments, heater 108 and/or bonding tool 110 can include gas channels configured to supply a cooling fluid (e.g., a gas, forced gas, forced air, nitrogen, etc.) to cool a semiconductor element. In certain bonding machines (e.g., thermocompression bonding machines) it may be desirable to heat bonding tool 110. Thus, while FIGS. 1A-1E illustrate a separate heater 108 for heating bonding tool 110 (e.g., for heating semiconductor element 112 including a plurality of conductive structures 112a), it will be appreciated that heater 108 and bonding tool 110 may be integrated into a single element (e.g., a heated bonding tool). In other embodiments of the invention, the bonding tool (and the semiconductor element carried by the bonding tool—including the conductive structures on the semiconductor element) may be heated by a laser, for example, in a laser assisted bonding process.

Bond head assembly 106 carries a bond head manifold 114 for receiving and distributing fluids (e.g., deoxidizing agents, gases, liquids, vapors, plasmas, etc.) as desired in a given application. As used herein, the terms “fluid” and “gas” are intended to be broadly construed (e.g., including referring to a state of matter without a fixed shape and/or is capable of flowing). In accordance with certain exemplary embodiments of the invention, bonding systems (e.g., bonding systems) may provide a “gas” for reducing oxides on conductive structures of a substrate and/or a semiconductor element. Such a gas may include a carrier gas (e.g., nitrogen, argon, etc.), where such a carrier gas may be a mixture of gases (e.g., nitrogen and hydrogen mix, etc.). For example, the gas may be a reducing gas (e.g., formic acid vapor, acetic acid vapor), a plasma gas (e.g., including a carrier gas such as nitrogen), a gas including attached electrons (e.g., including a carrier gas such as a nitrogen and hydrogen mix), etc.

As illustrated, bond head manifold 114 is illustrated connected to a deoxidizing agent source 118 (e.g., a bubbler system, a gas tank, a plasma source, etc.) via piping 120 (e.g., including hard piping, flexible tubing, a combination of both, or any other structure adapted to carry the deoxidizing agents and/or fluids described herein). In certain embodiments, deoxidizing agent source 118 may be a vapor generation system such as a bubbler type system including an acid fluid (e.g., formic acid, acetic acid, etc.). In certain embodiments, deoxidizing agent source 118 may be configured to supply a plasma gas to reduce or remove oxides (e.g., on semiconductor element 112 and/or substrate 104). For example, deoxidizing agent source 118 may be a plasma gas delivery system (or connected to a plasma gas delivery system).

Throughout the drawings, bond head manifold 114 is illustrated in a cross-sectional view; it should be understood the bond head manifold 114 may surround bonding tool 110 (e.g., bond head manifold 114 surrounding bonding tool 110 in a coaxial configuration). Bond head manifold 114 may have different configurations from that illustrated in the drawings. Further, it is understood that certain details of bond head manifold 114 (e.g., interconnection with piping 120, structural details for distributing a deoxidizing agent within bond head manifold 114, structural details for distributing a shielding gas within bond head manifold 114, structural details for drawing a vacuum through a center channel of bond head manifold 114, etc.) are omitted for simplicity.

Bond head manifold 114 includes three channels 114a, 114b, 114c having different functions. Channel 114a (e.g., outer channel) receives a shielding gas (e.g., an inert gas, a nitrogen gas, etc.) from a shielding gas supply (e.g., included in deoxidizing agent source 118 or fluidically connected with deoxidizing agent source 118). That is, a shielding gas is provided from a shielding gas supply (e.g., a nitrogen supply), through piping 120, to channel 114a of bond head manifold 114. From channel 114a of bond head manifold 114, a shielding gas 122 is provided as a shield from the outer environment.

Channel 114c (e.g., inner channel) receives a deoxidizing agent 124 via piping 120, and provides a deoxidizing agent 124 to an area including semiconductor element 112 and substrate 104 in connection with a bonding operation.

As will be appreciated by those skilled in the art, the specific design of a bond head manifold (or a different delivery system for providing the deoxidizing agent) may vary considerably. For example, in certain embodiments of the invention, a shielding gas may not be provided by a bond head manifold. Likewise, in certain embodiments of the invention, an exhaust system local to the bond head manifold may not be utilized. For example, in a bonding system utilizing a plasma gas as the deoxidizing agent, such a shielding gas (and/or local exhaust system) may not be deemed critical, and thus may not be included in the bonding system.

Bonding machine 100 includes a support structure 102 for supporting a substrate 104 during a bonding operation (where substrate 104 includes a plurality of conductive structures 104a). Support structure 102 may include any appropriate structure for the specific application. Support structure 102 includes a top plate 102a (configured to directly support substrate 104), a chuck 102c, and a heater 102b disposed therebetween. In applications where heat for heating substrate 104 is desirable in connection with the bonding operation, a heater such as heater 102b may be utilized. In other embodiments of the invention, support structure 102 (and a substrate supported by support structure 102—including conductive structures on the substrate) may be heated by a laser, for example, in a laser assisted bonding process.

In connection with a bonding operation, semiconductor element 112 is bonded to substrate 104 using bonding tool 110. During the bonding operation, corresponding ones of conductive structures 112a (e.g., electrically conductive structures) of semiconductor element 112 are bonded (e.g., using heat, force, ultrasonic energy, etc.) to respective ones of conductive structures 104a (e.g., electrically conductive structures) of substrate 104. Bond head manifold 114 provides a deoxidizing agent 124 (e.g., a reducing gas including a saturated vapor gas) in the area of semiconductor element 112 and substrate 104 in connection with a bonding operation. After deoxidizing agent 124 is distributed in the area of semiconductor element 112 and substrate 104, deoxidizing agent 124 contacts surfaces of each of conductive structures 112a/104a of semiconductor element 112 and substrate 104. The surfaces of conductive structures 104a/112a may then include a reaction product (e.g., where the reaction product is provided as a result of (i) a surface oxide on conductive structures 112a/104a, and (ii) deoxidizing agent 124 from deoxidizing agent source 118). This reaction product is desirably removed from the bonding area (i.e., the area where conductive structures 112a of semiconductor element 112 are bonded to corresponding conductive structures 104a of substrate 104) using a vacuum provided through channel 114b (e.g., a center channel) of bond head manifold 114 via exit piping 116.

Referring specifically now to FIG. 1A, bond head assembly 106 is illustrated positioning semiconductor element 112 above substrate 104. Semiconductor element 112 includes a plurality of conductive structures 112a. At room temperature, the plurality of conductive structures 112a are substantially planar with a dielectric surface 112b of semiconductor element 112. In another embodiment of the invention, at room temperature the plurality of conductive structures 112a are recessed with respect to dielectric surface 112b of semiconductor element 112. In another embodiment of the invention, at room temperature the plurality of conductive structures 112a protrude with respect to dielectric surface 112b of semiconductor element 112. Substrate 104 includes a plurality of conductive structures 104a. At room temperature, the plurality of conductive structures 104a are substantially planar with a dielectric surface 104b of substrate 104. In another embodiment of the invention, at room temperature the plurality of conductive structures 104a are recessed with respect to dielectric surface 104b of substrate 104. In another embodiment of the invention, at room temperature the plurality of conductive structures 104a protrude with respect to dielectric surface 104b of substrate 104.

While FIG. 1A illustrates the plurality of conductive structures 112a being substantially planar with dielectric surface 112b of semiconductor element 112, and the plurality of conductive structures 104a being substantially planar with dielectric surface 104b of substrate 104, FIG. 1A may not be at room temperature. As is known to those skilled in the art, heat may be applied to semiconductor element 112 and/or substrate 104 at varying levels during the bonding process. Thus, heat may be applied at the position shown in FIG. 1A, but additional heat may be applied to expand the conductive structures 112a/104a.

In FIG. 1B, semiconductor element 112 is lowered by bond head assembly 106 and provided at a position separated from substrate 104. Such a position may be considered (i) a post-alignment position, (ii) a pre-bonding position, or (iii) another position (e.g., a predetermined position) as desired. Bond head manifold 114 is illustrated providing shielding gas 122 and deoxidizing agent 124. Shielding gas 122 (e.g., an inert gas, a gas including nitrogen, etc.) is provided in an area surrounding semiconductor element 112 and substrate 104. Deoxidizing agent 124 is illustrated being distributed in proximity to a bonding area of semiconductor element 112 and substrate 104.

In certain embodiments, heat may be provided from heater 108 and/or heater 102b (or other heating elements, such as a laser for laser assisted bonding). As illustrated, conductive structures 112a of semiconductor element 112 have been heated and have expanded in shape (i.e., expanded in a direction toward substrate 104) and are now labelled as conductive structures 112a′. Similarly, conductive structures 104a of substrate 104 have been heated and expanded in shape (i.e., expanded in a direction toward semiconductor element 112) and are now labelled as conductive structures 104a′. Deoxidizing agent 124 may contact the surfaces of each of the conductive structures 112a′ of semiconductor element 112 and each of the conductive structures 104a′ of substrate 104.

In FIG. 1C, conductive structures 112a′ of semiconductor element 112 are brought into contact with corresponding conductive structures 104a′ of substrate 104.

That is, because of the expansion of conductive structures 112a′ and conductive structures 104a′—conductive structures 112a′ and conductive structures 104a′ are able to contact each other while a gap is maintained between dielectric surface 112b and dielectric surface 104b.

In FIG. 1D, conductive structures 112a′ of semiconductor element 112 have been bonded to conductive structures 104a′ of substrate 104. For example, each of conductive structures 112a′ and conductive structures 104a′ may be formed from copper or a copper alloy. While conductive structures 112a′ are bonded to conductive structures 104a′ in FIG. 1D, this bonding may be a partial bonding, where a complete bonding is accomplished in a future step (e.g., in an annealing oven).

In FIG. 1E, semiconductor element 112 has now been bonded to substrate 104. That is, each conductive structures 112a′ from FIG. 1D is illustrated having been bonded to a corresponding conductive structure 104a′, thereby forming bonded portions 126. Thus, during the bonding operation, corresponding ones of conductive structures 112a′ of semiconductor element 112 are bonded (e.g., using heat, force, ultrasonic energy, etc.) to respective ones of conductive structures 104a′ of substrate 104 to form bonded portions 126. Although six conductive structures 112a′ of semiconductor element 112′ are illustrated bonded to six conductive structures 104a′ of substrate 104, the invention is not so limited. It is understood that any number of conductive structures 112a′ can be bonded to any number of conductive structures 104a′. For example, two or more conductive structures 112a′ can be bonded to one conductive structure 104a′. In another example, two or more conductive structures 104a′ can be bonded to one conductive structure 112a′.

In FIG. 1E, bond head manifold 114 is illustrated no longer providing deoxidizing agent 124 and shielding gas 122. Bond head assembly 106 is illustrated having been moved away (e.g., along the Z-axis) from support structure 102, with semiconductor element 112 now bonded to substrate 104. With bond head assembly 106 moved away, and with the heat applied to semiconductor element 112 and/or substrate 104 removed (or at least reduced), dielectric surface 112b of semiconductor element 112 is bonded to dielectric surface 104b of substrate 104. That is, the gap between semiconductor element 112 and substrate 104 is closed because of the contraction of the expansion that occurred by heating conductive structures 112a and/or conductive structures 104a. When the gap no longer exists between semiconductor element 112 and substrate 104, dielectric surface 112b of semiconductor element 112 fuses to dielectric surface 104b of substrate 104 (e.g., because of a chemical bond or chemical reaction between the materials of dielectric surface 112b and dielectric surface 104—when those materials are in contact with one another), thereby forming a bonded substrate 104′.

FIGS. 1B-1D illustrate bond head manifold 114 providing deoxidizing agent 124 (e.g., a reducing gas, formic acid, plasma, plasma gas, etc.) and shielding gas 122 (e.g., an inert gas, a gas including nitrogen, etc.) continuously (i.e., prior to and during bonding). However, the invention is not so limited. For example, in certain embodiments, the deoxidizing agent may be provided at various different times, for example: just prior to bonding; prior to heating conductive structures 112a; during heating of conductive structures 112a; after heating of conductive structures 112a; etc.

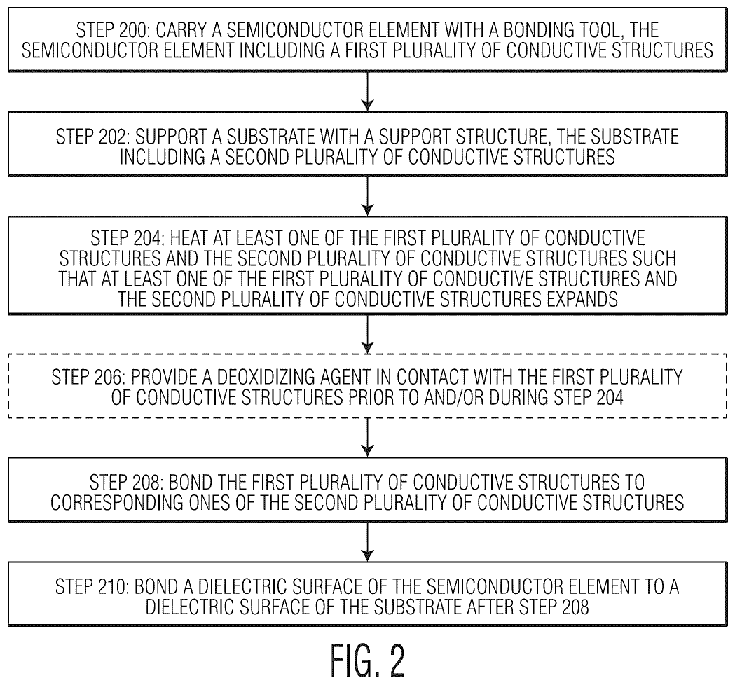

FIG. 2 is a flow diagram illustrating a method of bonding a semiconductor element to a substrate. As is understood by those skilled in the art, certain steps included in the flow diagram may be omitted; certain additional steps may be added; and the order of the steps may be altered from the order illustrated—all within the scope of the invention.

At Step 200, a semiconductor element is carried with a bonding tool, where the semiconductor element includes a first plurality of conductive structures (e.g., see semiconductor element 112 including conductive structures 112a, carried by bonding tool 110 in FIG. 1A). For example, the bonding tool may carry the semiconductor element from a die supply source (e.g., a semiconductor wafer) towards a substrate. At Step 202, a substrate is supported with a support structure, where the substrate includes a second plurality of conductive structures (e.g., see substrate 104 including conductive structures 104a, supported by support structure 102 in FIG. 1A).

At Step 204, at least one of the first plurality of conductive structures and the second plurality of conductive structures is heated such that at least one of the first plurality of conductive structures and the second plurality of conductive structures expands (e.g., see expanded conductive structures 112a′ and 104a′ in FIG. 1B). For example, the first plurality of conductive structures and the second plurality of conductive structures may expand in a range of: 5 to 100 nanometers; or 20 to 80 nanometers. Of course, other ranges are contemplated. For example, the first plurality of conductive structures may be heated by a first heater engaged with the bonding tool (e.g., see heater 108), and the second plurality of conductive structures may be heated by a second heater engaged with the support structure (e.g., see heater 102b). However, the invention is not limited to such embodiments. For example, at least one of the first plurality of conductive structures and the second plurality of conductive structures may be heated using laser energy (e.g., a laser assisted bonding process).

At optional Step 206, a deoxidizing agent (e.g., a reducing gas, a plasma gas, etc.) is provided in contact with the first plurality of conductive structures prior to or during Step 204 (e.g., see deoxidizing agent 124 in FIGS. 1B-1D). At Step 208, the first plurality of conductive structures are bonded to corresponding ones of the second plurality of conductive structures (e.g., see conductive structures 112a′ bonded to conductive structures 104a′ in FIG. 1D, and shown as bonded portions 126 in FIG. 1E). At Step 210, a dielectric surface of the semiconductor element is bonded to a dielectric surface of the substrate after Step 208 (e.g., see dielectric surface 112b of FIG. 1D bonded to dielectric surface 104b of FIG. 1D in FIG. 1E).

Although the invention is illustrated and described primarily with respect to a deoxidizing agent distributed through a bond head assembly, it is not limited thereto. As will be appreciated by those skilled in the art, a deoxidizing agent may be provided in a number of different configurations, such as, for example, through a support structure configured to support a substrate. More specifically, as shown in U.S. Pat. No. 11,205,633 (see FIGS. 11A-11D therein), a reducing gas (i.e., an example of a deoxidizing agent described herein) may be provided through a support structure.

Although not explicitly described in connection with the various embodiments of the invention disclosed herein, during bonding of a semiconductor element to a substrate, ultrasonic energy and/or force may be utilized, as is known to those skilled in the art.

Although the invention is illustrated and described herein with reference to specific embodiments, the invention is not intended to be limited to the details shown.

Rather, various modifications may be made in the details within the scope and range of equivalents of the claims and without departing from the invention.

1. A method of bonding a semiconductor element to a substrate, the method comprising the steps of:
(a) carrying the semiconductor element with a bonding tool, the semiconductor element including a first plurality of conductive structures;
(b) supporting the substrate with a support structure, the substrate including a second plurality of conductive structures;
(c) heating at least one of the first plurality of conductive structures and the second plurality of conductive structures such that the at least one of the first plurality of conductive structures and the second plurality of conductive structures expands;
(d) bonding the first plurality of conductive structures to corresponding ones of the second plurality of conductive structures; and
(e) bonding a dielectric surface of the semiconductor element to a dielectric surface of the substrate after step (d).

2. The method of claim 1 wherein during step (c) the first plurality of conductive structures are heated by a first heater engaged with the bonding tool, and the second plurality of conductive structures are heated by a second heater engaged with the support structure.

3. The method of claim 1 wherein during step (c) the at least one of the first plurality of conductive structures and the second plurality of conductive structures are heated using laser energy.

4. The method of claim 1 wherein during step (c) each of the first plurality of conductive structures and the second plurality of conductive structures expands.

5. The method of claim 1 wherein during step (c) each of the first plurality of conductive structures and the second plurality of conductive structures expand in a range of 5 to 100 nanometers.

6. The method of claim 1 wherein during step (c) each of the first plurality of conductive structures and the second plurality of conductive structures expand in a range of 20 to 80 nanometers.

7. The method of claim 1 wherein at room temperature the first plurality of conductive structures are substantially planar with the dielectric surface of the semiconductor element.

8. The method of claim 1 wherein at room temperature the first plurality of conductive structures are recessed with respect to the dielectric surface of the semiconductor element.

9. The method of claim 1 wherein at room temperature the first plurality of conductive structures protrude with respect to the dielectric surface of the semiconductor element.

10. The method of claim 1 wherein at room temperature the second plurality of conductive structures are substantially planar with the dielectric surface of the substrate.

11. The method of claim 1 wherein at room temperature the second plurality of conductive structures are recessed with respect to the dielectric surface of the substrate.

12. The method of claim 1 wherein at room temperature the second plurality of conductive structures protrude with respect to the dielectric surface of the substrate.

13. The method of claim 1 wherein the first plurality of conductive structures and the second plurality of conductive structures are formed of copper.

14. The method of claim 1 wherein the first plurality of conductive structures and the second plurality of conductive structures are formed of a copper alloy.

15. The method of claim 1 wherein the dielectric surface of the semiconductor element is bonded to the dielectric surface of the substrate during step (e) because of contraction of expansion that occurred during step (c).

16. The method of claim 1 wherein the dielectric surface of the semiconductor element is configured to fuse to the dielectric surface of the substrate during step (e) because of contact therebetween.

17. The method of claim 1 wherein contact between (i) the dielectric surface of the semiconductor element and (ii) the dielectric surface of the substrate is caused by contraction of expansion that occurred during step (c).

18. The method of claim 1 further comprising a step of providing a deoxidizing agent in contact with the first plurality of conductive structures prior to or during step (c).

19. The method of claim 18 wherein the deoxidizing agent includes at least one of a reducing gas and a plasma gas.

20. The method of claim 18 wherein the deoxidizing agent includes a reducing gas, the reducing gas including formic acid.
